(19) United States
(12) Patent Application Publication
(10) Pub. No.: US 2013/0220222 A1
(43) Pub. Date: Aug. 29, 2013

(54) Gas Distribution Apparatus with Heat Exchanging Channels

(71) Applicants: Tsan-Hua Huang, Tainan City (TW); Miao-Chan Wu, Kaohsiung City (TW)

(72) Inventors: Tsan-Hua Huang, Tainan City (TW); Miao-Chan Wu, Kaohsiung City (TW)

(73) Assignee: HERMES-EPITEK CORPORATION, TAIPEI CITY (TW)

(21) Appl. No.: 13/403,193

(22) Filed: Feb. 23, 2012

(51) Int. Cl. C23C 16/455; B05C 11/00

(52) U.S. Cl. 118/713; 118/724

(57) ABSTRACT

The invention provides a gas distribution apparatus comprising a main frame and a cover. The main frame includes a plurality of walls having a plurality of second gas channels therein, a plurality of first plenums defined by the walls, a plurality of heat exchange channels, a plurality of first gas channels under the first plenums, a plurality of heat exchange channel covers on the heat exchange channel, and a plurality of first plenum covers on the first plenums. Each first plenum and two adjacent walls defining the first plenum form a trunk with a plurality of branches extending from the trunk, and the branches of adjacent trunks are arranged in an interlaced manner. Each heat exchange channel is between two adjacent trunks. The cover on the main frame encloses a second plenum thereon.

### BACKGROUND OF THE INVENTION

1. Field of the Invention

The present invention generally relates to an apparatus for gas distribution, and more particularly to a gas distribution apparatus with heat exchanging channels.

2. Description of Related Art

In semiconductor manufacturing processes such as thin film deposition processes or chemical vapor deposition (CVD) processes which are carried out inside a chamber provided with a showerhead, semiconductor wafers are placed on a wafer carrier with a heating function and the showerhead sprays reaction gases required for the processes into the chamber and over the semiconductor wafers on the wafer carrier. When reaction gases such as precursor gases containing materials to be deposited are sprayed onto the semiconductor wafers through the showerhead in a gas state, a chemical reaction occurs within the chamber, and thus the thin film is formed thereon. During the chemical reaction, a high temperature must be maintained inside the chamber for the chemical reaction.

The showerhead usually has a gas distribution injector for directing the precursor gases towards the wafer carrier in the chamber where the semiconductor wafers can be treated for processes. Ideally, the precursor gases are directed at the wafer carrier such that the precursor gases react as close to the wafer and distribute as uniform as possible over the semiconductor wafers.

In many metal organic chemical vapor deposition (MOCVD) processes, for example, combinations of precursor gases including metal organics and hydrides, such as ammonia or arsine, etc., are introduced into a chamber through the showerhead. Process-facilitating carrier gases, such as inert gases, argon or helium, also may be introduced into the chamber through the showerhead. The precursor gases mix in the chamber and react to form a thin film on a semiconductor wafer held within the chamber. The carrier gases typically aid in maintaining laminar flow at the wafer carrier.

However, many existing showerheads have problems that may interfere with efficient operation or uniform deposition due to the design of gas channel. For example, gas spray in existing showerhead may induce significant space in the chamber without effective gas flow from the gas vents of the showerhead to the semiconductor wafer resulting in a non-uniform distribution of gases. For some types of precursors and under certain process conditions, it is desirable to prevent mixing the precursors prior to reaching the wafer deposition surface to prevent premature reaction of the precursors and the production of undesirable particulates and reaction products.

The non-uniform distribution of gases may cause unwanted deposition or non-uniform deposition. Such unwanted deposition consumes reactants and decreases the efficiency and the non-uniform deposition would further reduce the throughput of the process. Thus, many current systems require frequent cleaning of the reactor, which further reduces productivity.

Since a high temperature must be maintained inside the chamber for the chemical reaction, uniform and efficient cooling channel design is crucial for maintaining the efficiency, throughput and productivity of the reactor. Some existing showerheads also have problems of efficient operation or uniform deposition due to the cooling design. Owing to the inefficient cooling design, the formation of condensates on the showerhead as well as gas phase particle formation and the production of undesirable precursor reactant products may adversely affect the composition of the thin film deposited on the semiconductor wafers. In U.S. Published Patent Application No. 20070163440, the gas separation type showerhead which separately provides two different gases without cooling design might cause reaction and undesirable deposition on the holes and vents and form obstacles to the gas flows. In U.S. Pat. No. 7976631, each the heat exchanging channel of the showerhead is arranged only adjacent to one side of two adjacent gas channels and such cooling design obviously cannot provide uniform heat exchange. In U.S. Published Patent Application No. 20090095222, the gas mixing channel and the heat exchanging channel of the showerhead both are spiral channels wherein the gas mixing channel is disposed adjacent to the heat exchanging channel. The heat exchanging channel is also arranged only adjacent to one side of two adjacent gas channels and this inefficient cooling design would result in the formation of condensates on the showerhead as well as gas phase particle formation.

Therefore, there is a need for an improved deposition apparatus and process that can provide uniform thin film deposition and heat exchanging performance.

### SUMMARY OF THE INVENTION

One embodiment of the invention provides a gas distribution apparatus comprising a main frame and a cover. The main frame includes a plurality of walls having a plurality of second gas channels therein, a plurality of first plenums defined by the walls connecting to a gas delivery apparatus, a plurality of heat exchange channels, a plurality of first gas channels under the first plenums, a plurality of heat exchange channel covers on the heat exchange channel, and a plurality of first plenum covers on the first plenums. Each the first plenum and the walls defining the first plenum form a trunk with a plurality of branches extending from the trunk, and the branches of adjacent trunks are arranged in an interlaced manner. Each the heat exchange channel is between two adjacent trunks. The cover on the main frame encloses a second plenum thereon.

Another embodiment of the invention provides a deposition system. The deposition system comprises a chamber enclosing a processing volume and a gas delivery apparatus. The gas distribution apparatus comprises a main frame and a cover on the main frame to enclose a second plenum thereon. The main frame includes a plurality of walls having a plurality of second gas channels therein, a plurality of first plenums defined by the walls connecting to the gas delivery apparatus, a plurality of heat exchange channels, a plurality of first gas channels connecting the first plenums and the processing volume, a plurality of heat exchange channel covers on the heat exchange channel, and a plurality of first plenum covers on the first plenums. Each the first plenum and the walls defining the first plenum form a trunk with a plurality of branches extending from the trunk, and the branches of adjacent trunks are arranged in an interlaced manner. The second gas channels connect the second plenum and the processing volume, the second plenum connects the second gas channels and the gas delivery apparatus.

In yet another embodiment, a method for forming a gas distribution apparatus is disclosed. The method comprises the following steps. First of all, a single piece of material is provided. Then the single piece of material is machined to form a main frame. The main frame includes a plurality of walls having a plurality of second gas channels therein, a plurality of first plenums defined by the walls, a plurality of heat exchange channels and a plurality of first gas channels under the first plenums. Each the first plenum and the walls defining the first plenum form a trunk with a plurality of branches extending from the trunk, and the branches of adjacent trunks are arranged in an interlaced manner. Each the heat exchange channel is between two adjacent trunks. Next a plurality of heat exchange channel covers are mounted on the heat exchange channel and a plurality of first plenum covers on the first plenums. Finally, a cover is mounted on the main frame to enclose a second plenum thereon, wherein the second gas channels connects the second plenum.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. The above and other features and advantages of the present invention will become more apparent by describing in detail exemplary embodiments thereof with reference to the attached drawings.

FIG. 1 is a cross-sectional view of the gas distribution apparatus with heat exchanging channels of one embodiment of the invention.

FIG. 1A is a detailed cross-sectional view of the gas distribution apparatus shown in

FIG. 1 according to one embodiment of the invention.

FIG. 1B is a detailed sectional bottom view of the gas distribution apparatus shown in FIG. 1 according to one embodiment of the invention.

FIG. 1C is a schematic view showing gas flow and heat exchange fluid flow respectively.

FIG. 1D is a sectional view taken along line D-D in FIG. 1.

FIG. 2 is a partial and cross sectional side view of the gas distribution apparatus according to one embodiment of the invention.

FIG. 3 is a side view of the gas distribution apparatus according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION OF THE INVENTION

Reference will now be made in detail to specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well known process operations and elements are not described in detail in order not to unnecessarily obscure the present invention.

The invention generally provides a gas distribution apparatus with heat exchanging channels. In one embodiment of the invention, the gas distribution apparatus with heat exchanging channels is applied in a deposition system such as a MOCVD system, but not limited to a MOCVD system. A typical deposition system usually comprises a chamber enclosing a processing volume, a gas delivery apparatus and the gas distribution apparatus. The gas distribution apparatus is disposed above the processing volume, and a substrate carrier is disposed under the processing volume. The substrate carrier is for holding at least one substrate which is loaded thereon for processing. Typical substrates loaded for processing in the deposition system includes silicon wafer, sapphire substrate, silicon carbide (SiC) substrate, or gallium nitride (GaN) or III-V semiconductor substrate, etc. It is to be understood that other types of substrates, such as glass substrates, may be processed in the deposition system. It is noted that any suitable designs of the chamber enclosing a processing volume and the gas delivery apparatus of the deposition system could be used in the deposition system and thus no particular examples will be specifically described and shown herein. The deposition system could further include other necessary devices or elements which are obvious for those with ordinary skill in the art. However, some apparatus or device which relate to the gas distribution apparatus will be mentioned in the following description.

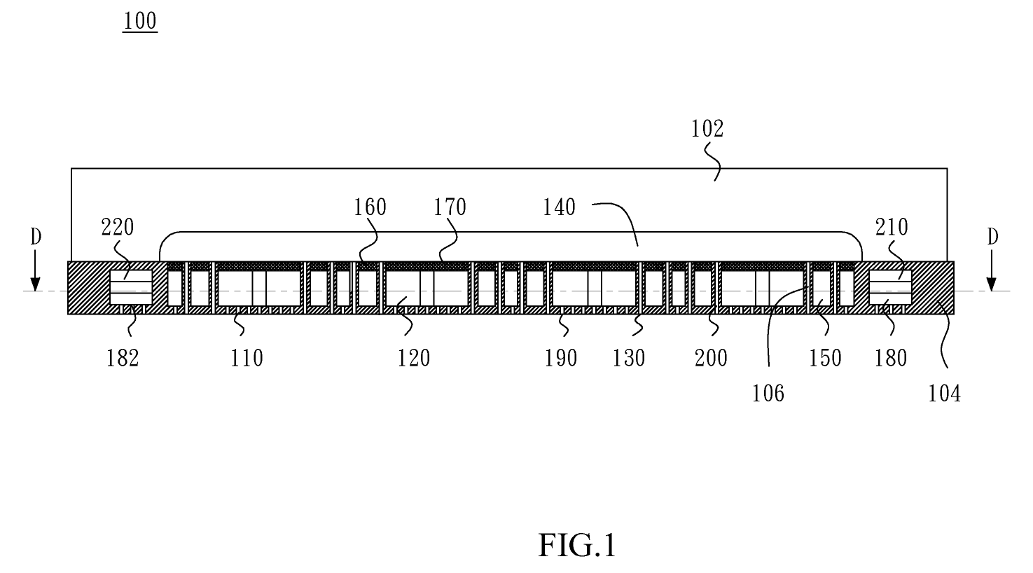

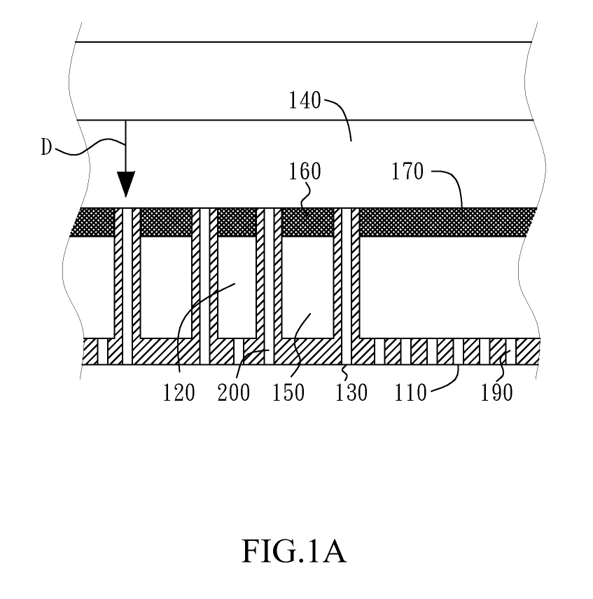

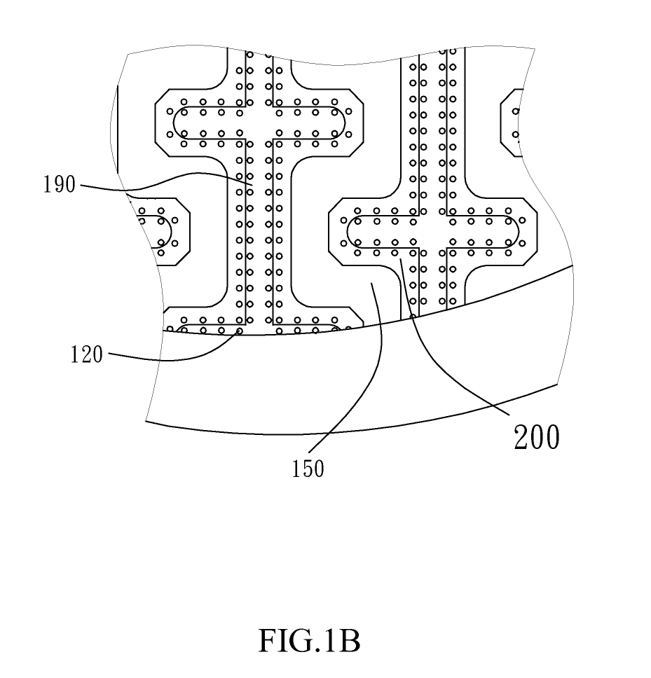

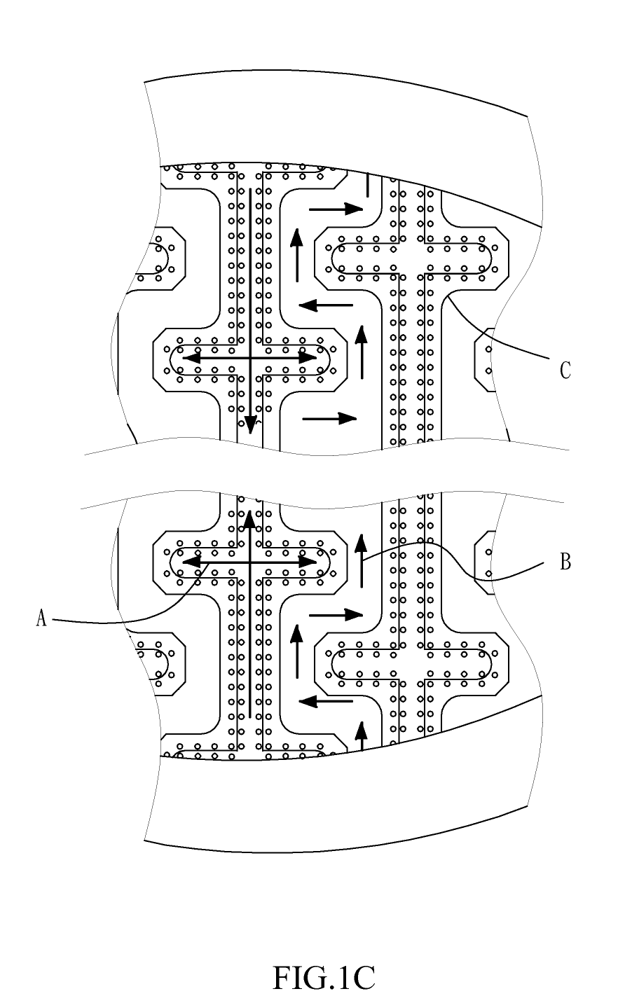

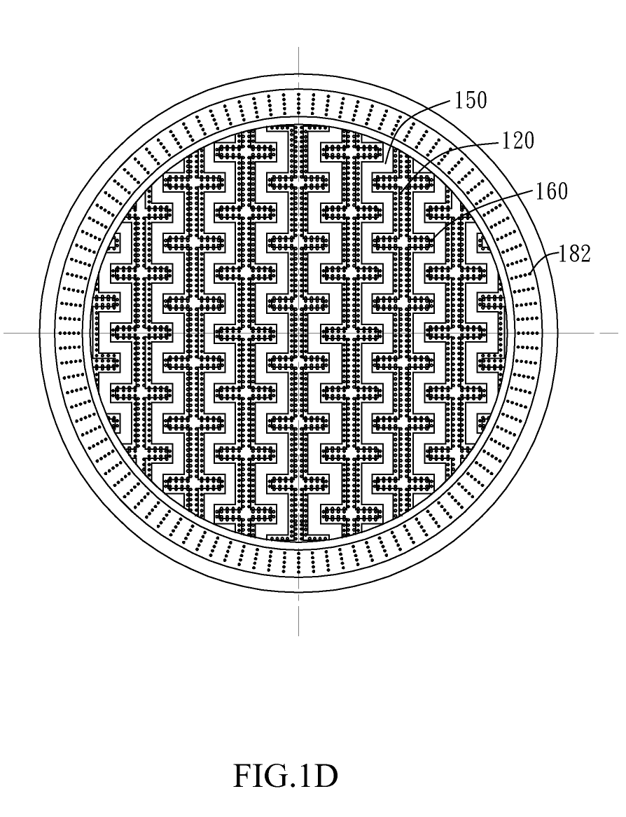

FIG. 1 is a cross-sectional view of the gas distribution apparatus with heat exchanging channels of one embodiment of the invention. The gas distribution apparatus 100 includes a cover 102 and a main frame 104. The cover 102 is mounted on the main frame 104 to form a second plenum 140. The main frame 104 includes a plurality of first plenums 120, first gas channels 190, walls 106 with second gas channels 200, and heat exchange channels 150. The main frame 104 further comprises a first gas supply plenum 210, an exterior heat exchange fluid plenum 220 and a purge gas supply plenum 180 on the peripheral portion of the main frame 104 surrounding the first plenum 120, the first gas channels 190, the second gas channels 200, and the heat exchange channels 150. In one embodiment, the exterior heat exchange fluid plenum 220 is between the first gas supply plenum 210 and the purge gas supply plenum 180. The main frame 104 also includes heat exchange channel covers 160 and first plenum covers 170 mounted on the heat exchange channels 150 and the first plenum 120 respectively.

The first gas supply plenum 210, the purge gas supply plenum 180 and the second plenum 140 connect to the gas delivery apparatus. The gas delivery apparatus includes multiple gas sources depending on the process being performed. Different gases, such as precursor gases, carrier gases, or others may be supplied from the gas delivery apparatus to the first gas supply plenum 210, the purge gas supply plenum 180 and the second plenum 140 of the gas distribution apparatus through various supply lines. The supply lines may include control valves and flow controllers or other types of controllers to monitor and regulate or shut off the flow of gas in each line.

The first gas supply plenum 210 connects to the first plenum 120 and the first gas channels 190 such that the gas from the gas delivery apparatus can flow through and be distributed by the gas distribution apparatus. The first gas channels 190 are formed in the bottom of the main frame 104 under the first plenums 120. A first gas vent 110 is at the bottom of each first gas channel 190 which connects to the processing volume under the gas distribution apparatus. In one embodiment, the first gas vents 110 comprise drilled holes. A plurality of first plenum covers 170 are mounted on the first plenums 120 to isolate the first plenums 120 and the second plenum 140.

The second plenum 140 connects to the second gas channels 200 such that the gas from the gas delivery apparatus can flow through and be distributed by the gas distribution apparatus. A second gas vent 130 is at the bottom of each second gas channel 200 which connects to the processing volume under the gas distribution apparatus. The second gas vent 130 comprises drilled holes.

The exterior heat exchange fluid plenum 220 is located between the first gas supply plenum 210 and the purge gas supply plenum 180 and connects to the heat exchange channels 150. A heat exchanging fluid or water may flow through the exterior heat exchange fluid plenum 220 to the heat exchange channels 150 to regulate the temperature of the gas distribution apparatus. The heat exchanging fluid may be circulated through a heat exchanger to control the temperature of the heat exchanging fluid as required to maintain the temperature of the gas distribution apparatus within a desired temperature range. A plurality of heat exchange channel covers 160 are mounted on the heat exchange channels 150 to confine the heat exchanging fluid or water in the heat exchange channels 150 and to isolate the heat exchange channels 150 and the second plenum 140.

The purge gas supply plenum 180 connects to a plurality purge gas channels 182 such that the purge gas from the gas delivery apparatus can flow through the gas distribution apparatus. The purge gas comprises an inert gas. The purge gas from the gas delivery apparatus flows into the purge gas supply plenum 180 and moves downstream toward the substrates in the processing volume under the gas distribution apparatus.

FIG. 1A is a detailed cross-sectional view of the gas distribution apparatus shown in FIG. 1 according to one embodiment of the invention. The first and second gases can flow from the gas delivery apparatus to the first plenum 120 and the second plenum 140 and then into the first gas channels 190 and the second gas channels 200 respectively. The first and second gases spray into the processing volume under the gas distribution apparatus through the first gas vents 110 and the second gas vent 130 respectively. The sizes and shapes of the first gas vents 110 and the second gas vent 130 can be chosen depending on the gases flowing through. The first plenum 120 and the heat exchange channels 150 are separated by walls 106 while the second gas channels 200 are through the walls 106. The thickness of the wall 106 may be selected according to the requirements such as cooling. For example, a thinner wall may provide better cooling efficiency than a thicker one.

FIG. 1B is a detailed sectional bottom view of the gas distribution apparatus shown in FIG. 1 according to one embodiment of the invention. As shown in FIG. 1B, the first plenum 120 and the walls 106 defining or enclosing the first plenum 120 constitute a combination of a trunk with a plurality of branches extending from the trunk. The branches of adjacent trunks are arranged in an interlaced manner. Also shown in FIG. 1B is the heat exchange channels 150 in a tortuous or zigzag manner. In one embodiment, the heat exchange channels 150 comprise a plurality of alternative and continuous [symbol] and [symbol] shaped conduits, and the first plenum 120 has a plurality of continuous cross shaped plenums. The corners of the wall 106 are rounded so as to smooth the flow of the heat exchanging fluid. The heat exchange channels 150 and the first plenum 120 are formed and isolated through the walls 106 with the second gas channels 200. Moreover, the first gas channels 190 and the second gas channels 200 are arranged in a one-on-one manner such that each the first gas channel 190 corresponds to each the second gas channel 200.

FIG. 1C is a schematic view showing gas flow and heat exchange fluid flow respectively. The first gas flows A are from the gas delivery apparatus through the gas supply plenum 210 on the exterior circular portion of the gas distribution apparatus. The first gas then flows through the first gas channels 190 and sprays out via the first gas vents 110 into the processing volume under the gas distribution apparatus. The second gas flow C is from the gas delivery apparatus through the second plenum 140 and the second gas flows through the second gas channels 200 in the walls 106 and sprays out via the second gas vent 130 into the processing volume under the gas distribution apparatus. The heat exchange fluid flow B is from a pipe line through the exterior heat exchange fluid plenum 220 to the heat exchange channels 150 across the gas distribution apparatus to regulate the temperature of the gas distribution apparatus.

The flow rate of the heat exchanging fluid or water may also be adjusted to help control the temperature of the gas distribution apparatus 100. Additionally, the thicknesses of walls 106 may be designed to facilitate temperature regulation of the gas distribution apparatus 100. Thinner walls 106 may increase the rate of thermal transfer through the wall and thereby increase the cooling rate of the gas distribution apparatus 100.

FIG. 1D is a sectional view taken along line D-D in FIG. 1. As shown in FIG. 1D, the first plenums 120 and the walls 106 constitute a plurality of combinations each having a trunk with a plurality of branches extending from the trunk. In this embodiment, the branches of adjacent trunks are arranged in an interlaced manner so as to form the heat exchange channels 150 with a plurality of alternative and continuous [symbol] and [symbol] shaped conduits. The purge gas channels 182 are arranged on the exterior circular portion of the gas distribution apparatus 100.

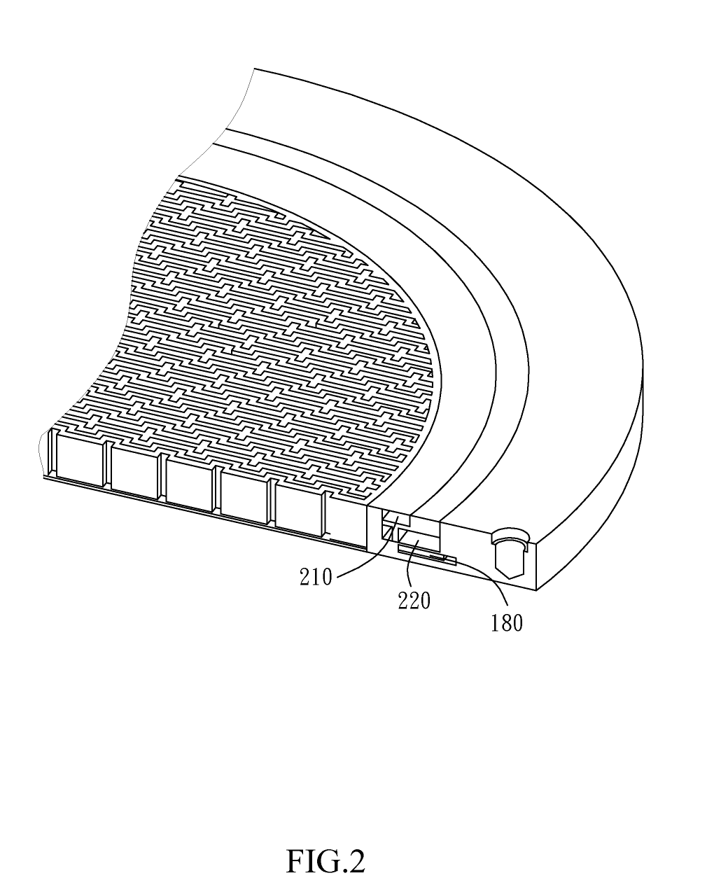

FIG. 2 is a partial and cross-sectional side view of the gas distribution apparatus according to one embodiment of the invention. The first gas supply plenum 210, the exterior heat exchange fluid plenum 220 and the purge gas supply plenum 180 can be seen in the main frame 104. Also shown in FIG. 2, the heat exchange channel covers 160 and the first plenum covers 170 are mounted on the heat exchange channels 150 and the first plenums 120 respectively. The heat exchange channel covers 160 and the first plenum covers 170 can be mounted on the heat exchange channels 150 and the first plenum 120 by laser welding which is repairable. The advantages of laser welding include high yield ratio and easy-to-apply. The main frame 104 can be formed by machining a single piece of material so that any leaking problem of the heat exchanging fluid or water can be avoided. The main frame 104 with the heat exchange channels 150 and the first plenum 120 or the walls 106 can be formed by a machining center.

Referring back to FIG. 1D, the first gas channels 190, the second gas channels 200 and the purge gas channels 182 can be formed by electrical discharge machining (EDM) in a single process. It is noted that the numbers of the first gas channels 190, the second gas channels 200 and the purge gas channels 182 may be as large as possible.

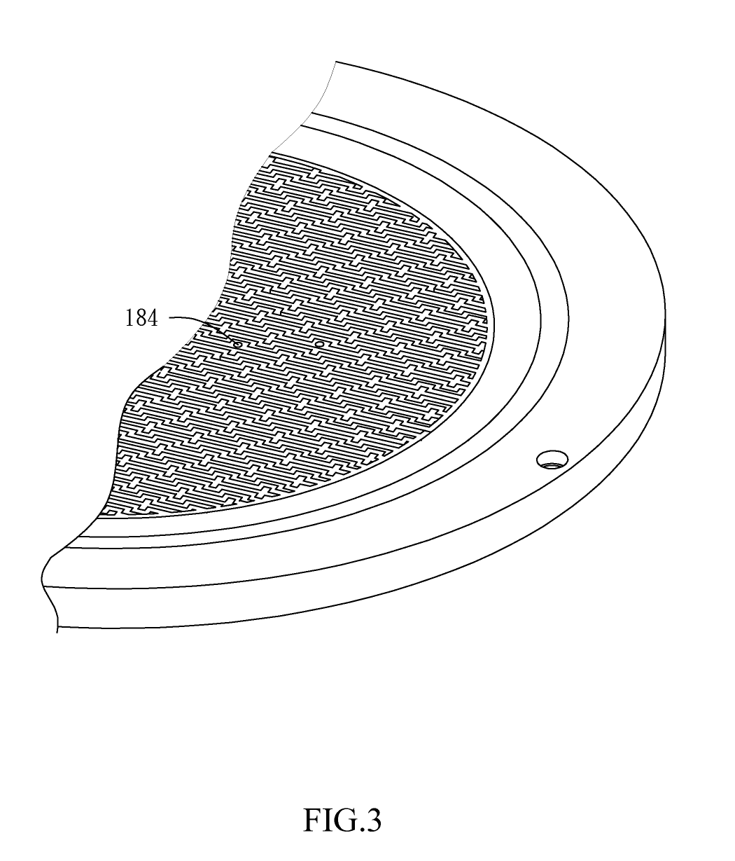

FIG. 3 is side view of the gas distribution apparatus according to one embodiment of the invention. Several viewports 184 are shown in FIG. 3. The viewports 184 are formed in the gas distribution apparatus 100 to permit viewing of the deposition process. The viewports 184 extend through the gas distribution apparatus to permit the operators of a deposition system to observe the deposition process.

While the present invention has been particularly shown and described with reference to exemplary embodiments thereof, the exemplary embodiments should be considered in descriptive sense only and not for purposes of limitation. Therefore, it will be understood by those skilled in the art that various changes in form and details may be made therein without departing from the spirit and scope of the invention as defined by the appended claims.

What is claimed is:

1. A gas distribution apparatus, comprising:
a main frame including:
a plurality of walls having a plurality of second gas channels therein;
a plurality of first plenums defined by the walls connecting to a gas delivery apparatus, wherein each the first plenum and the walls defining the first plenum form a trunk with a plurality of branches extending from the trunk, and the branches of adjacent trunks are arranged in an interlaced manner;
a plurality of heat exchange channels, wherein each the heat exchange channel is between two adjacent trunks;
a plurality of first gas channels under the first plenums;
a plurality of heat exchange channel covers on the heat exchange channel; and
a plurality of first plenum covers on the first plenums;
a cover on the main frame to enclose a second plenum thereon, wherein the second plenum connects the second gas channels and the gas delivery apparatus.

2. The gas distribution apparatus of claim 1, wherein the main frame further comprises a first gas supply plenum, an exterior heat exchange fluid plenum and a purge gas supply plenum surrounding the first plenum, the walls and the heat exchange channels on the peripheral portion of the main frame, wherein the first gas supply plenum connects the first plenums and the gas delivery apparatus.

3. The gas distribution apparatus of claim 2, wherein the exterior heat exchange fluid plenum is between the first gas supply plenum and the purge gas supply plenum.

4. The gas distribution apparatus of claim 2, wherein the main frame further comprises a plurality of purge gas channels under the purge gas supply plenum.

5. The gas distribution apparatus of claim 1, wherein the heat exchange channels comprise a plurality of alternative and continuous [symbol] and [symbol] shaped conduits, and each the first plenum has a plurality of continuous cross shaped plenums.

6. The gas distribution apparatus of claim 1, wherein the first gas channels and the second gas channels are arranged in a one-on-one manner such that each the first gas channel corresponds to each the second gas channel.

7. The gas distribution apparatus of claim 1 further comprising at least one viewport in the gas distribution apparatus to permit viewing of a deposition process.

8. The gas distribution apparatus of claim 1, wherein the walls have rounded corners.

9. A deposition system, comprising:
a chamber enclosing a processing volume;
a gas delivery apparatus; and
a gas distribution apparatus, comprising:
a main frame including:
a plurality of walls having a plurality of second gas channels therein;
a plurality of first plenums defined by the walls connecting to the gas delivery apparatus, wherein each the first plenum and the walls defining the first plenum form a trunk with a plurality of branches extending from the trunk, and the branches of adjacent trunks are arranged in an interlaced manner;
a plurality of heat exchange channels, wherein each the heat exchange channel is between two adjacent trunks;
a plurality of first gas channels connecting the first plenums and the processing volume;
a plurality of heat exchange channel covers on the heat exchange channel; and
a plurality of first plenum covers on the first plenums;
a cover on the main frame to enclose a second plenum thereon, wherein the second gas channels connect the second plenum and the processing volume, the second plenum connects the second gas channels and the gas delivery apparatus.

10. The deposition system of claim 9, wherein the deposition system comprises a metal organic chemical vapor deposition system.

11. The deposition system of claim 9 further comprising a substrate carrier at one end of the processing volume.

12. The deposition system of claim 9, wherein the main frame further comprises a plurality of first gas vents, wherein each first gas vent is at the bottom of each first gas channel.

13. The deposition system of claim 9, wherein the main frame further comprises a plurality of second gas vents, wherein each second gas vent is at the bottom of each second gas channel.

14. The deposition system of claim 9, wherein the main frame further comprises a first gas supply plenum, an exterior heat exchange fluid plenum and a purge gas supply plenum surrounding the first plenum, the walls and the heat exchange channels on the peripheral portion of the main frame, wherein the first gas supply plenum connects the first plenums and the gas delivery apparatus.

15. The deposition system of claim 14, wherein the exterior heat exchange fluid plenum is between the first gas supply plenum and the purge gas supply plenum.

16. The deposition system of claim 14, wherein the main frame further comprises a plurality of purge gas channels under the purge gas supply plenum.

17. The deposition system of claim 9, wherein the heat exchange channels comprise a plurality of alternative and continuous [symbol] and [symbol] shaped conduits, and each the first plenum has a plurality of continuous cross shaped plenums.

18. The deposition system of claim 9, wherein the first gas channels and the second gas channels are arranged in a one-on-one manner such that each the first gas channel corresponds to each the second gas channel.

19. A method for forming a gas distribution apparatus, comprising:
providing a single piece of material;
machining the single piece of material to form a main frame, the main frame including:
a plurality of walls having a plurality of second gas channels therein;
a plurality of first plenums defined by the walls, wherein each the first plenum and the walls defining the first plenum form a trunk with a plurality of branches extending from the trunk, and the branches of adjacent trunks are arranged in an interlaced manner;
a plurality of heat exchange channels, wherein each the heat exchange channel is between two adjacent trunk; and
a plurality of first gas channels under the first plenums;
mounting a plurality of heat exchange channel covers on the heat exchange channel and a plurality of first plenum covers on the first plenums; and
mounting a cover on the main frame to enclose a second plenum thereon, wherein the second gas channels connect the second plenum.

20. The method according to claim 19, wherein the single piece of material is machined by a machining center.

21. The method according to claim 19, wherein the heat exchange channel covers and the first plenum covers are mounted on the heat exchange channels and the first plenums respectively by laser welding.

22. The method according to claim 19, wherein the first gas channels and the second gas channels are formed by electrical discharge machining (EDM) in a single process.
